(19) United States
(12) Patent Application Publication
(10) Pub. No.: US 2025/0208061 A1
(43) Pub. Date: Jun. 26, 2025

(54) FAULT ISOLATION FOR SEMICONDUCTOR DEVICE MANUFACTURING

(71) Applicant: Intel Corporation, Santa Clara, CA (US)

(72) Inventors: Megan KNAPP, Hillsboro, OR (US); John NUGENT, Corrales, NM (US); Thaddeus COX, Lake Oswego, OR (US); Kevin MARCON, St. Helens, OR (US)

(21) Appl. No.: 18/395,943

(22) Filed: Dec. 26, 2023

(51) Int. Cl. G01N 21/95; H01L 21/3065; H01L 21/66

(52) U.S. Cl. CPC G01N 21/9501; H01L 21/3065; H01L 22/12

(57) ABSTRACT

Devices and methods that are useful for fault isolation in microelectronic devices are provided. A portion of a microelectronic device to be analyzed is grounded through the creation of a cavity in the device surface. Voltage contrast provides the ability to identify individual failure sites on the microelectronic device. The grounding of the portion of the device can be reversed and a different portion of the microelectronic device grounded for additional voltage contrast analysis and fault identification. These processes can be repeated a number of times to probe multiple chained structures.

### FIELD

Descriptions are generally related to semiconductor device manufacturing, and more particular descriptions are related to fault isolation in test structures for semiconductor device manufacturing.

### BACKGROUND

Semiconductor chips are central to intelligent devices and systems, such as personal computers, laptops, tablets, phones, servers, and other consumer and industrial products and systems. Manufacturing semiconductor chips presents a number of challenges and these challenges are amplified as devices become smaller and performance demands increase. Challenges include, for example, unwanted material interactions, precision and scaling requirements, power delivery requirements, limited failure tolerance, and material and manufacturing costs.

Design validation, failure analysis, and debugging techniques are critical parts of semiconductor product development, integrated circuit chip design, manufacturing process development, and product yield improvement. Engineering samples are generated to perform necessary validation of new products and design changes. Validation includes debugging any design, process, and/or logic issues. Additionally, circuit-level analysis is used to identify any design, timing, power, and process issues. Identifying and isolating circuits and devices that are not functioning properly is critical to failure analysis techniques. Failure analysis can include isolating and probing problematic or malfunctioning circuits in a semiconductor device. Test structures containing part or all of a semiconductor device are manufactured and tested before final manufacturing processes are created. These test structures make it possible to identify and isolate features and manufacturing processes that are leading to low yields.

### BRIEF DESCRIPTION OF THE DRAWINGS

The figures are provided to aid in understanding the invention. The figures can include diagrams and illustrations of exemplary structures, assemblies, data, methods, and systems. For ease of explanation and understanding, these structures, assemblies, data, methods, and systems, the figures are not an exhaustively detailed description. The figures therefore should not be understood to depict the entire metes and bounds of structures, assemblies, data, methods, and systems possible without departing from the scope of the invention. Additionally, features are not necessarily illustrated relatively to scale due in part to the small sizes of some features and the desire for clarity of explanation in the figures.

FIG. 1 illustrates example metallization layers on a surface of a semiconductor chip.

FIG. 2 provides an alternate view of metallization layers.

FIG. 3 shows a partial circuit diagram for an exemplary microelectronic device useful in semiconductor manufacturing processes.

FIG. 4 provides an example microelectronic device that has been prepared for fault analysis.

FIG. 5 illustrates example voltage contrast results for an example microelectronic device that has been prepared for fault analysis.

FIG. 6 shows example voltage contrast results for an additional example microelectronic device that has been prepared for fault analysis.

FIGS. 7A and 7B illustrate cross-sections of cavities created by a milling process in an exemplary microelectronic device.

FIG. 8 diagrams a method for analyzing a microelectronic device using voltage contrast.

FIG. 9 provides an exemplary computing system.

Descriptions of certain details and implementations follow, including non-limiting descriptions of the figures, which depict some examples and implementations.

### DETAILED DESCRIPTION

References to one or more examples are to be understood as describing a particular feature, structure, or characteristic included in at least one implementation of the invention. The phrases “one example” or “an example” are not necessarily all referring to the same example or embodiment. Any aspect described herein can potentially be combined with any other aspect or similar aspect described herein, regardless of whether the aspects are described with respect to the same figure or element.

The words “connected” and/or “coupled” can indicate that two or more elements are in direct physical or electrical contact with each other. The term “coupled,” however, can also mean that two or more elements are not in direct contact with each other and are instead separated by one or more elements but they may still co-operate or interact with each other, for example, physically, magnetically, or electrically.

The words “first,” “second,” and the like, do not indicate order, quantity, or importance, but rather are used to distinguish one element from another. The words “a” and “an” herein do not indicate a limitation of quantity, but rather denote the presence of at least one of the referenced items. The terms “follow” or “after” can indicate immediately following or following after some other event or events. Other sequences of operations can also be performed according to alternative embodiments. Furthermore, additional operations may be added or removed depending on the particular application.

Disjunctive language such as the phrase “at least one of X, Y, or Z,” is used in general to indicate that an element or feature, may be either X, Y, or Z, or any combination thereof (e.g., X, Y, and/or Z). Thus, this disjunctive language should be understood not to imply that certain embodiments require at least one of X, at least one of Y, or at least one of Z to each be present.

Terms such as chip, die, IC (integrated circuit) chip, IC die, microelectronic chip, microelectronic die, semiconductor device, and/or semiconductor chip are interchangeable and refer to a device having integrated circuits and comprising semiconducting materials.

The terms “package,” “packaging,” “IC package,” or “chip package,” “microelectronics package,” or “semiconductor chip package” are interchangeable and generally refer to an enclosed carrier of one or more dies, in which the dies are attached to a package substrate and encapsulated. The package substrate provides electrical interconnects between the die(s) and other dies and/or a motherboard or other printed circuit board for I/O (input/output) communication and power delivery. A package with multiple dies can, for example, be a system in a package.

A package substrate generally includes dielectric layers or structures having conductive structures on and/or embedded within the dielectric layers or structures. The dielectric layers can be, for example, build-up layers. Other structures or devices are also possible within a package substrate. Semiconductor package substrates can have cores or be coreless. Semiconductor packages having cores can have dielectric layers such as buildup layers on more than one side of a core, such as two sides of a core.

A “core” or “package core” generally refers to a layer usually embedded within a package substrate. The core can provide structure or stiffness to a package substrate. A core is an optional feature of a package substrate. The core can be a dielectric organic or inorganic material and may have conductive vias extending through the layer. A package core can, for example, comprise glass (such as, for example, aluminosilicate, borosilicate, alumino-borosilicate, silica, and fused silica), silicon, silicon nitride, silicon carbide, gallium nitride, or aluminum oxide. In some examples, core materials are glass-fiber reinforced organic resins such as epoxy-based resins. A further example package substrate core is FR4 (woven glass fiber reinforces epoxy).

Flow diagrams as illustrated herein provide examples of sequences of various process actions. The flow diagrams can indicate operations to be executed by a software or firmware routine, as well as physical operations. Physical operations can be performed by semiconductor modification, testing, and imaging equipment that is operated through user input and software and/or firmware routines. Although shown in a particular sequence or order, unless otherwise specified, the order of the actions can be modified. Thus, the illustrated diagrams should be understood only as examples, and the process can be performed in a different order, and some actions can be performed in parallel. Additionally, one or more actions can be omitted and not all implementations will perform all actions.

Various components described can be a means for performing the operations or functions described. Each component described can include software, hardware, or a combination of these. Some components can be implemented as software modules, hardware modules, special-purpose hardware (for example, application specific hardware, application specific integrated circuits (ASICs), digital signal processors (DSPs), etc.), embedded controllers, or hardwired circuitry). Other components can be semiconductor processing and/or testing equipment that is able to perform physical operations such as, for example, milling, imaging, probing, material deposition (for example, chemical vapor deposition, atomic layer deposition, and/or sputtering), chemical mechanical polishing, and etching.

To the extent various computer operations or functions are described herein, they can be described or defined as software code, instructions, configuration, and/or data. The software content can be provided via an article of manufacture with the content stored thereon, or via a method of operating a communication interface to send data via the communication interface. A machine-readable storage medium can cause a machine to perform the functions or operations described. A machine-readable storage medium includes any mechanism that stores information in a tangible form accessible by a machine (e.g., computing device), such as recordable/non-recordable media (e.g., read only memory (ROM), random access memory (RAM), magnetic disk storage media, optical storage media, flash memory devices). Instructions can be stored on the machine-readable storage medium in a non-transitory form. A communication interface includes any mechanism that interfaces to, for example, a hardwired, wireless, or optical medium to communicate to another device, such as, for example, a memory bus interface, a processor bus interface, an Internet connection, a disk controller.

Semiconductor chip manufacturing processes are sometimes divided into front end of the line (FEOL) processes and back end of the line (BEOL) processes. Electronic circuits and active and passive devices within the chip, such as for example, transistors, capacitors, resistors, and/or memory cells, are manufactured in what can be referred to as FEOL processes. Memory cells include, for example, electronic circuits for random access memory (RAM), such as static RAM (sRAM), dynamic RAM (DRAM), read only memory (ROM), non-volatile memory, and/or flash memory. FEOL processes can be, for example, complementary metal-oxide semiconductor (CMOS) processes. BEOL processes include metallization of the chip where interconnects are formed in layers and the feature size of the interconnect increases in layers nearer the surface of the semiconductor chip. Semiconductor chip interconnects can also be referred to as traces.

Semiconductor chip interconnects can be created by forming a trench or though-layer via by etching a trench or via structure into a dielectric layer and filling the trench or via with metal. Dielectric layers can comprise, for example, low-κ dielectrics, SiO₂, silicon nitride (SiN), silicon carbide (SiC), and/or silicon carbonitride (SiCN). Low-κ dielectrics include for example, fluorine-doped SiO₂, carbon-doped SiO₂, porous SiO₂, porous carbon-doped SiO₂, combinations for the foregoing, and also these materials with airgaps. Dielectric layers that include conducting features can be intermetal dielectric (ILD) features.

Semiconductor devices are typically manufactured in parallel on wafers. The wafers are diced apart to create individual devices. Metallization layers for semiconductor chips are typically manufactured while the semiconductor chips are housed on a wafer. Test structures for metallization layers for a semiconductor device can be created on wafers that do not contain transistors and other devices. Creating test structures for metallization layers for a semiconductor chip design can allow isolation of issues causing low yields.

In some devices power and signal input/output (I/O) is delivered through metallization layers on the semiconductor chip surface. Metallization layers typically comprise conducting metal traces housed in layers of dielectric material. Metal traces typically are comprised of copper. In some semiconductor chips power and signal I/O are delivered on the same side of the chip (e.g., backside metallization), in some other semiconductor chips, power is delivered on one side of the chip and signal I/O are on the other side of the chip (e.g., backside and frontside metallization).

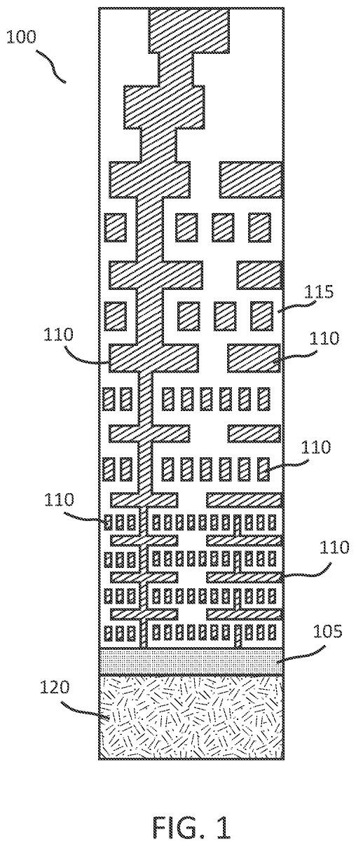

FIG. 1 illustrates a section of an exemplary portion of an integrated circuit chip 100 that has metallization layers on a surface of the device region 105. FIG. 1 is a cross-sectional view. The metallization layers in this example are typically referred to as front side metallization layers. It is sometimes the case that a semiconductor chip has metallization on a first side to provide signal I/O and metallization on a second side that provides power to the semiconductor devices. In other examples, signal I/O and power are provided to the semiconductor chip on one side of the chip. In some semiconductor devices, metallization layers are on the front side and the back side of the device region 105. The semiconductor device region 105 houses semiconductor devices such as transistors. Types of possible transistors include, ribbon field effect transistors (FETs) nanowire FETs which are a types of gate-all-around (GAA) transistors. Other types of transistors include planar FETs and fin FETs. Field effect transistors typically are metal-oxide-semiconductor field-effect (MOSFET) transistors. A semiconductor device can contain more than one type of transistor. Metallization regions include conducting metal traces 110 and layers of dielectric 115 (individual layers are not delineated in FIG. 1A). The dielectric layers 115 can be ILDs. The conducting metal traces 110 can be trenches and vias that have been created in the dielectric regions 115 that are filled with a metal, such as, for example copper. The semiconductor device region 105 has typically been manufactured on a substrate 120. A substrate 120 can be, for example, a silicon or silicon-on-insulator substate. Other materials for substrates 120 include, gallium arsenide, germanium, indium antimonide, lead telluride, indium phosphide, indium antimonide, indium gallium arsenide, or gallium antimonide. Other types of substrates are also possible.

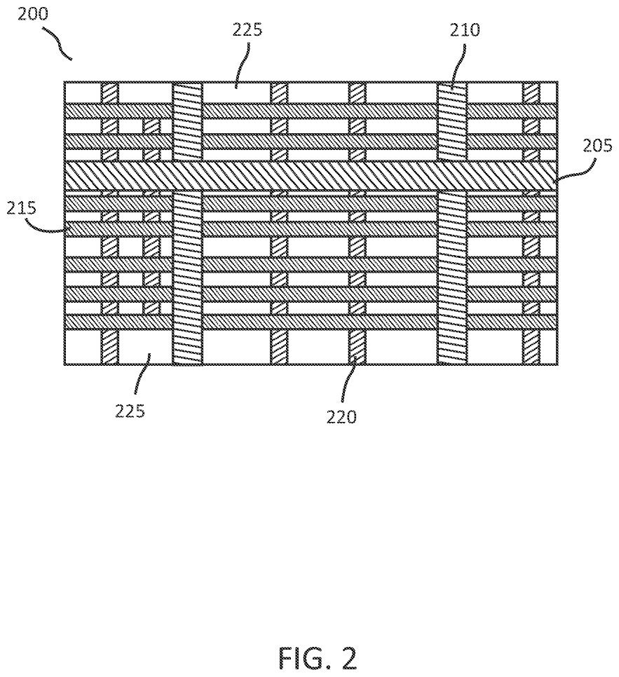

FIG. 2 illustrates an additional view of a portion of an exemplary metallization region 200. FIG. 1 is a cross-sectional view that illustrates a metallization region and FIG. 2 is a top-down-type view that illustrates a portion of a metallization region 200, however FIGS. 1 and 2 are not necessarily from the same device or section of a device. In FIG. 2, conducting metal traces 205, 210, 215, and 220 are in different levels of a metallization region. For example, trace 205 can be metal level 7 (M7), trace 210 can be metal level 6 (M6), trace 215 can be metal level 5 (M5), trace 220 can be metal level 4 (M4). FIG. 2 is a small portion of a complex metallization region on a semiconductor chip.

Conducting metal traces 205, 210, 215, and 220 are in dielectric layers 225 (individual layers would be stacked and not visible as individual layers in this view). Typically, a metallization level, such as that housing trace 205, 210, 215, or 220 will comprise a layer of dielectric having vias and trenches that are filled with a conducting material, such as a metal. The metal is typically copper. Dielectric layers 225 can be ILDs.

Semiconductor devices can undergo a sorting process in which the electrical function of the semiconductor device is validated. This process can identify semiconductor devices that are not functioning as desired. Electrical validation sorting can be done on devices while they are housed in a wafer. This type of sorting can be done, for example, using a device that holds the wafer in place (such as with a vacuum chuck), positions a probe card having microscopic contacts, and applies the microscopic contacts of the probe card to the landing pads of a device under test. It is sometimes necessary for a semiconductor device to have larger landing pads than otherwise necessary in order for the probe card to contact the device for testing. Devices identified as not functioning as desired at this stage can undergo further analysis to determine the location and cause of the failure.

Engineering samples or test vehicles that are microelectronic devices comprising microelectronic circuits can be created for various parts of a semiconductor device, such as for example, metallization regions. These engineering samples can be on substrates that do not comprise a device region having transistors. For engineering samples that do have transistors, voltage contrast is provided by the transistors regardless of whether a pad connection to a silicon substrate exists. If an engineering sample is created on a substrate without transistors, different validation techniques that do not rely on the voltage contrast provided by transistors in a device region of a substrate.

Voltage contrast (VC) fault isolation and failure analysis of integrated circuits to detect manufacturing defects and design faults, can be uncontrolled and passive. Voltage contrast fault isolation can be used for isolating yield-limiting defects for both inline and end of-line failure analysis methods. Integrated circuits structures are toggled for testing by landing one or more probe tips on large landing pads (which typically are 30-50 μm in one dimension, for example, a pad can be 50 μm by 50 μm) to bias the circuit, which can limit both the size of features and resolutions of the features that can be analyzed for manufacturing defects and design faults.

Yield engineering relies on the electrical data collected by landing probe cards on devices at, for example, an e-test (device electronic test) sort stage of manufacturing. Analysis of the output signals is the first quality characterization step for end of line products and test vehicles. Various test patterns and post data processing can narrow down where an electrical fault location is, but these are not always enough to move to transmission electron microscopy (TEM) imaging for defect analysis. These types of e-test sort toolsets lack an ability to scan a wafer surface.

The e-test sort data can be the first indication of low yield and can be used as a starting point for further fault isolation. Many debug paths on test chips involve preparing an individual die for nanoprobing. The material for testing and debug can be in wafer form. Testing preparation typically requires the wafer to be singulated to create dies. Nanoprobing involves landing probe tips on pads and scanning the region of interest with a scanning electron microscope (SEM), in order to isolate the location of a failing structure so that TEM analysis can be performed. Wafer level fault isolation on test chip can be considerably less time consuming because it does not require wafer dicing. Conductive atomic force microscopy (CAFM) can provide fault isolation for TEM imaging. However, rastering an atomic force microscopy (AFM) tip is more time consuming than rastering a charged beam.

Multi-site (or multiplexed) sort testing for interlaced semiconductor device structures can exhibit leakage during the biasing of the minimal electrical input needed to drive a device structure. Leakage can be removed by routing from the input to the semiconductor structure being tested.

Creating test structures for new back end process before integrating back end metallization with the transistors and transistor interconnects can enable higher yields in an overall chip. These test structures are useful, for example to qualify new tools, process recipes, materials, design rules marginality, before the added complexity of transistor voltage contrast. Being able to rapidly debug process or design rule-related defect modes in back end metallization facilitates semiconductor chip design and manufacture.

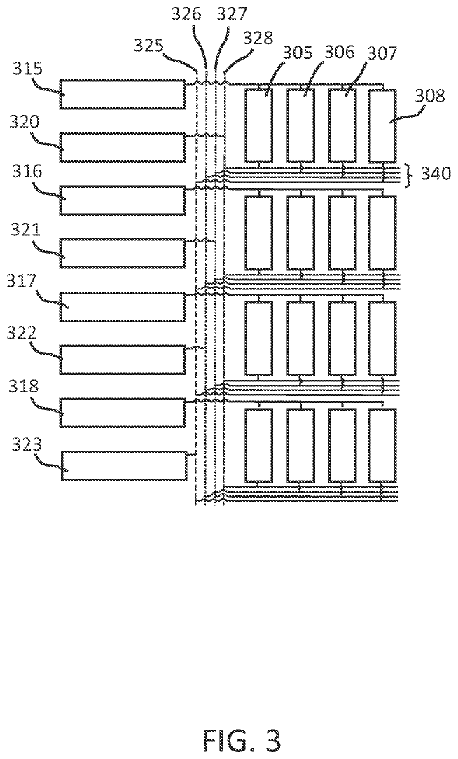

FIG. 3 illustrates a partial circuit diagram for a section of an exemplary test vehicle that comprises microelectronic circuits. The test vehicle of FIG. 3 can be one that is comprised of overlapping test structures 305 that comprise conducting metal traces in dielectric material. Ground probe pad 315 is electrically connected to test structures 305, 306, 307, and 308. Additional ground probe pads 316, 317, and 318 are similarly connected to test structures (not numbered). Output probe pads 320, 321, 322, and 323 are connected to bus wires 328, 327, 326, and 325 (dashed lines), respectively. Output probe pads 320, 321, 322, and 323 are multiplexed output probe pads and serve a number of test structures 305, 306, 307, and 308, respectively. Output probe pads 320, 321, 322, and 323 additionally serve other test structures (not numbered) that are connected through bus wires 328, 327, 326, and 325. Additional wires 340 connect test structures test structures 305, 306, 307, and 308 to bus wires 328, 327, 326, and 325, respectively.

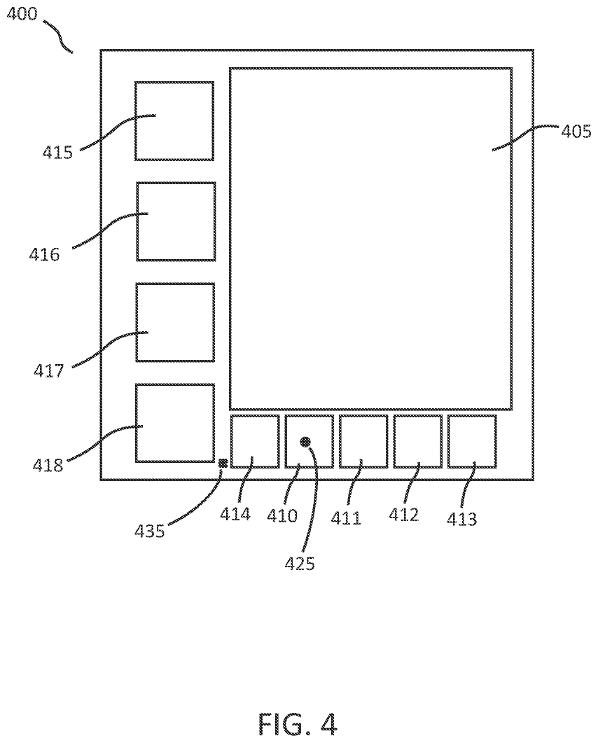

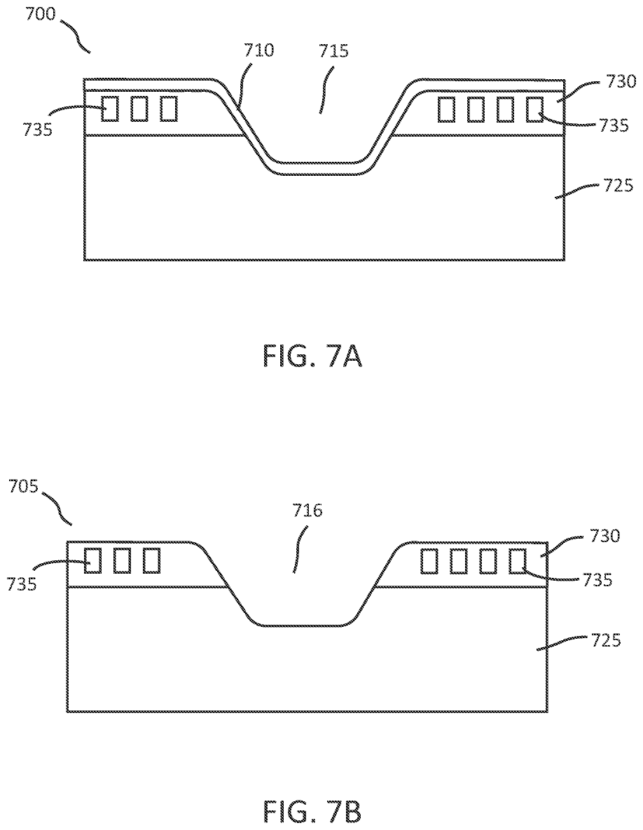

FIG. 4 illustrates an exemplary device 400 that can be used for testing. The exemplary device 400 can be a test vehicle, engineering sample, or a design rule validation or a design rule monitor sample. The exemplary device 400 comprises microelectronic circuit region 405 and probe pads 410, 411, 412, and 413 and common ground pad 414. Probe pad 410 comprises grounding region 425. Grounding region 425 can be created by drilling through probe pad 411 using a plasma focused ion beam (PFIB) to mill a cavity into the surface of exemplary device 400 onto which copper deposits during the process. Grounding region 425 is a cavity in the surface of exemplary device 400 where material has been removed from the surface of exemplary device 400. The grounding region 425 cavity is lined with copper metal causing the region to ground connected microelectronic circuits to the substrate. The bare beam PFIB milling process can redeposit copper from the conducting metal traces of the sample to ground the probe pad to the sample substrate. FIG. 7A provides an illustration of a cross-section of an example grounding region 425. Exemplary device 400 also includes an isolation trench 435 that electrically isolates one device in the exemplary device 400 from others. For example, if the exemplary device 400 is laid out in a similar manner to the circuit diagram of FIG. 3, isolation trench 435 can be used to isolate one test structure from the other three structures in the group by severing one of the bus wires 328, 327, 326, and 325 in one or more regions. Isolation trench 435 can be created, for example, by using image recognition to place a mill pattern on one or more routing lines to other test structures. The mill pattern can be created using PFIB with a gas chemistry that removes copper and/or prevents deposition of conductive species. The gas chemistry can make the materials from the milled section more volatile so that they are pumped away and/or the gas chemistry can react and leave redeposited materials non-conductive. Example gas chemistries include commercially available Dx gas from FEI Company (a subsidiary of Thermo Fisher Scientific). FIG. 7B provides an illustration of a cross-section of an example mill region where copper has not been deposited. Device sort (test) probe pads 415, 416, 417, and 418 that are associated with microelectronic circuit region 405, are also shown in FIG. 4. Device sort (test) probe pads 415, 416, 417, and 418 can be, for example, four interwoven chains with a common ground 414. Device sort (test) probe pads 415, 416, 417, and 418 can have routing to connect to probe pads 410, 411, 412, and 414 (not shown in FIG. 3).

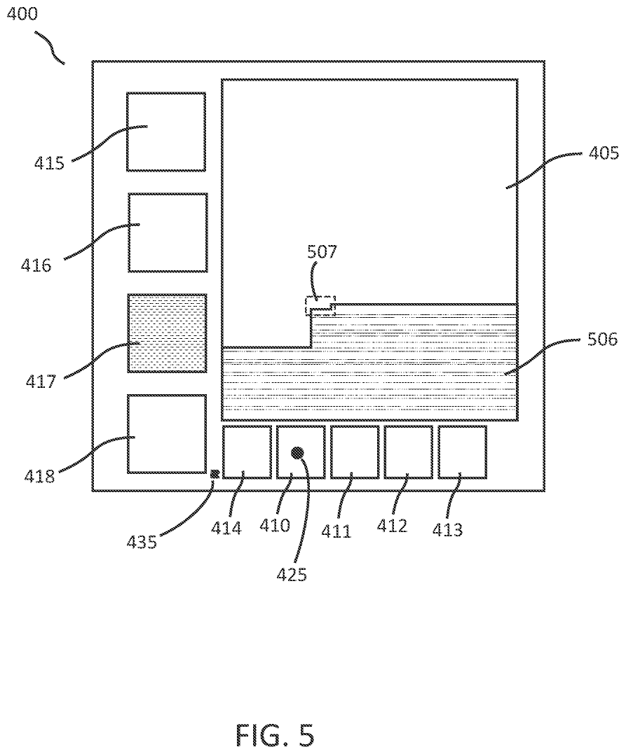

FIG. 5 reproduces failure analysis results that can be observed for an exemplary device 400 of FIG. 4. For parts in FIG. 5 that are numbered similarly as those in FIG. 4, the descriptions for those parts for FIG. 4 are applicable to FIG. 5. In FIG. 5, a PFIB is used to create a voltage contrast image of the microelectronic circuit region 405. A charge differential provides voltage contrast and provides an image for section 506 of microelectronic circuit region 405. The voltage contrast imaging can be done, for example, using a scanning electron microscope (SEM) or the PFIB to provide a charge differential. A detector, such as, for example, the secondary electron detector, detects the resulting contrast variation during beam rastering between the ground signals and the floating signals. If the test structure has no failure, then this test structure would appear dark. Floating structures appear bright (in the image) because the injected charge does not have a path to ground so it is more likely to eject secondary electrons. If two or more chains have a failure (short) anywhere, then the chain and the pad of the shorted structure will also darken. If the grounded chain is open (break in the chain defect) then the chain will be dark up to the point of the open and bright elsewhere. Signal tracing can reveal the likely source of the open and provide enough localization for failure analysis processes. Using a plasma-focused ion beam milling scanning electron microscope (PFIB SEM) can provide the ability to both create cavities in and image a microelectronic device. A failure location 507 (outlined by a dashed rectangle) in microelectronic circuit region 405 can be identified through the voltage contrast provided by, for example, the PFIB. Ground probe pad 417 has also shown a contrasting voltage.

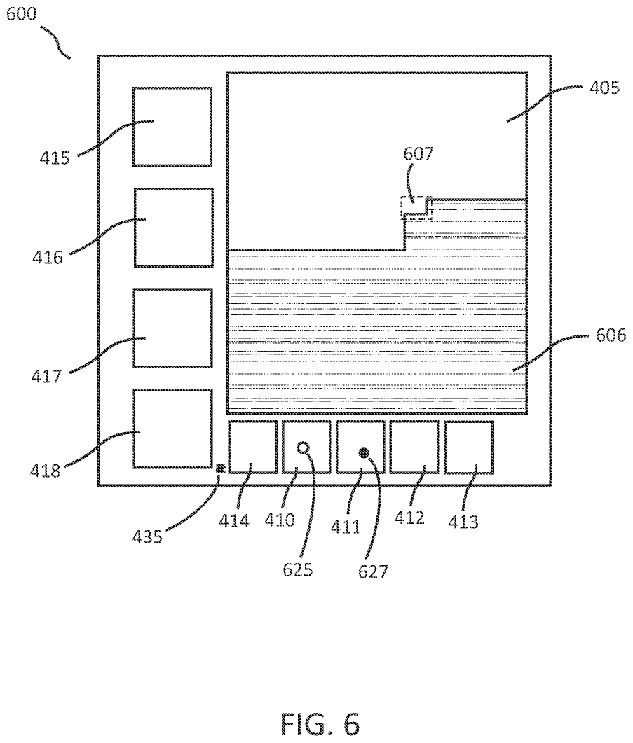

FIG. 6 reproduces further example failure analysis results for an exemplary device 600 that is a further modification of the device of FIGS. 4 and 5. For parts in FIG. 6 that are numbered similarly as those in FIG. 4, the descriptions for those parts for FIG. 4 are useful also for FIG. 6. The exemplary device 600 of FIG. 6 includes a non-conducting cavity 625 that was formerly a grounding region 425. Conducting material has been removed from grounding region 425, through, for example, milling the region with a PFIB and gas chemistry that removes copper so that copper does not deposit into the cavity 625 that is formed. FIG. 7B provides an illustration of a cross-section of an example mill region where copper has not been redeposited. Additionally, probe pad 411 has been grounded by grounding region 627. Grounding region 627 can be created by drilling through probe pad 411 using a plasma focused ion beam (PFIB) to mill a cavity into the surface of exemplary device 600 onto which copper deposits during the process. Grounding region 627 is a cavity in the surface of exemplary device 600 where material has been removed from the surface of exemplary device 600. The grounding region 627 cavity is lined with copper metal causing the region to ground connected microelectronic circuits to the substrate. The bare beam PFIB milling process can redeposit copper from the conducting metal traces of the sample to ground the probe pad to the sample semiconductor substrate. FIG. 7A provides an illustration of a cross-section of an example grounding region 627. In FIG. 6, a PFIB is used to create a voltage contrast image of the microelectronic circuit region 405. A charge differential provides voltage contrast and provides an image for section 606 of microelectronic circuit region 405. A failure location 607 (outlined by a dashed rectangle) in microelectronic circuit region 405 can be identified through the voltage contrast provide by the PFIB. Additional similar modifications can be performed on device 600 for failure analysis. For example, the grounding function of grounding region 627 can be reversed through a PFIB milling process that removes copper from the cavity. One or more new grounding regions can be created in one or both of probe pads 412 and 413 through a PFIB milling process that allows copper to deposit in the cavity created.

FIG. 7A shows a cross-section of a portion of an example microelectronic device 700 that includes a grounding region. The grounding region includes a copper layer 710 that is on the sidewalls of cavity 715. The grounding region can be created through a PFIB milling process in which copper is deposited on the sidewalls of the cavity 715 that is created by the milling process. In FIG. 7B, a cavity 716 has been created in microelectronic device 705 (of which a small portion is depicted). The cavity 716 does not have a conducting layer of copper on its sidewalls. Cavity 716 can be created by, for example, a PFIB milling process with a gas chemistry that prevents or inhibits conductive copper redeposition. Example gas chemistries include commercially available Dx gas from FEI Company. Cavity 716 can be created by milling a region in the surface of a microelectronic device, or it can be created by re-milling a cavity that already exists in the surface of a microelectronic device, such as, for example, cavity 715. Similarly, cavity 715 can be created in a surface of a microelectronic device or it can be created by re-milling a cavity that already exists in the surface of a microelectronic device, such as, for example, cavity 716. In FIGS. 7A and 7B, substrate 725 can be, for example, a silicon or silicon-on-insulator substrate. Other materials for substrates include, gallium arsenide, germanium, indium antimonide, lead telluride, indium phosphide, indium antimonide, indium gallium arsenide, or gallium antimonide. The foregoing materials can be semiconducting substrates. Other types of substrates are also possible and the examples herein are not limited to a particular type of semiconducting substrate. The microelectronic devices 700 and 705 also include a circuit layer 730, and conducting traces 735. Conducting traces 735 can be comprised of copper.

In general, ion beam processes deposit ions into the material that they are processing. Cavities created through the ion beam processes described herein can contain implanted ions from the ion beam. For example, the structures isolation trench 435, grounding region 425, non-conducting cavity 625, grounding region 627, cavity 715, and/or cavity 716 can contain implanted ions.

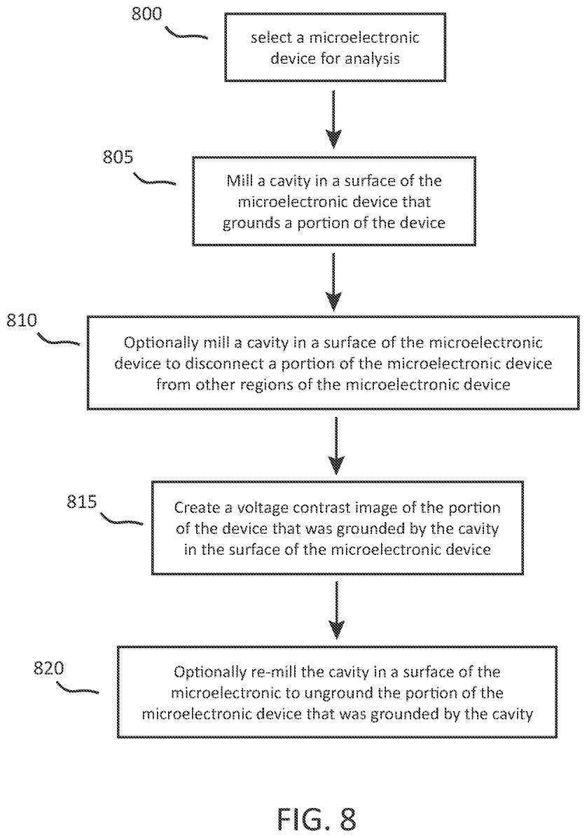

FIG. 8 presents a method for failure analysis of a microelectronic device. Failure analysis includes selecting a microelectronic device for analysis 800. The microelectronic device can be one that has not passed an electronic test sort. A hole is milled into the surface of the microelectronic device that creates a cavity having copper on its sidewalls 805. The cavity grounds a portion of the microelectronic device isolating that portion from other areas of the microelectronic device. The hole can be milled using, for example, a bare beam PFIB milling process. The ground cavity can be created in, for example, a test pad of the microelectronic device. The ground cavity can be, for example, similar to that shown in and described with respect to FIG. 7A. Optionally, a region of the surface of the microelectronic device is milled forming a hole that disconnects a portion of the microelectronic device from other regions of the microelectronic device 810. The location for the disconnection cavity can be determined, for example, by using image recognition. The disconnection cavity can be milled using a PFIB milling process with a gas chemistry that prevents conducting metal redeposition into the disconnection cavity that is created. The disconnection cavity can be, for example, similar to that shown in and described with respect to FIG. 7B. Example gas chemistries include commercially available Dx gas from FEI Company. The microelectronic device can be analyzed using voltage contrast imaging 815. The voltage contrast imaging can be done, for example, using a scanning electron microscope (SEM). It is also possible to use a plasma-focused ion beam milling scanning electron microscope (PFIB SEM) that provides the ability to both create cavities in and to image a microelectronic device. Specifically, voltage contrast can be used to identify fault locations in the portion of the microelectronic device that was grounded by the cavity in the surface of the microelectronic device 815. Optionally, the grounding cavity can be re-milled to un-ground the cavity using a PFIB milling process with a gas chemistry that prevents metal redeposition into the re-milled cavity 820. The microelectronic device can continue to be tested by milling ground cavities in new areas, such as other test pads. The method of FIG. 8 can be used on a device that is a chip or on a device housed on a wafer (i.e., the wafer has not been singulated to create individual microelectronic chips). Testing devices that are in wafer form can save time since singulation is not necessary before testing and analysis. The failure analysis method of FIG. 8 does not require landing probe tips on a device being tested. In example methods, individual failure sites (fault locations) on devices can be determined with a spatial resolution of 10 to 100 nm.

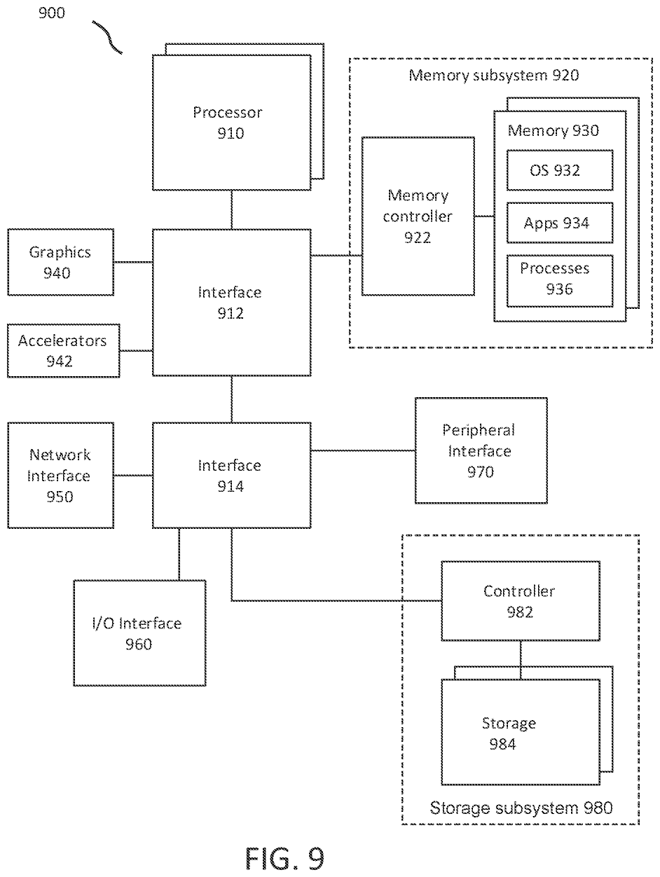

FIG. 9 depicts an example computing system which can be used in conjunction with milling and imaging equipment used to test microelectronic devices. The computing system can be a system used for running equipment in a semiconductor manufacturing and testing setting. For example, instructions for performing one or more aspects of the process described herein and with respect to FIG. 8 can be stored and/or run on the computing system. Further, the samples tested can be for semiconductor chips that are various components of the computing system. The computing system employed can include more, different, or fewer features than the one described with respect to FIG. 9.

Computing system 900 includes processor 910, which provides processing, operation management, and execution of instructions for system 900. Processor 910 can include any type of microprocessor, CPU (central processing unit), GPU (graphics processing unit), processing core, or other processing hardware to provide processing for system 900, or a combination of processors or processing cores. Processor 910 controls the overall operation of system 900, and can be or include, one or more programmable general-purpose or special-purpose microprocessors, DSPs, programmable controllers, ASICs, programmable logic devices (PLDs), or the like, or a combination of such devices.

In one example, system 900 includes interface 912 coupled to processor 910, which can represent a higher speed interface or a high throughput interface for system components needing higher bandwidth connections, such as memory subsystem 920 or graphics interface components 940, and/or accelerators 942. Interface 912 represents an interface circuit, which can be a standalone component or integrated onto a processor die. Where present, graphics interface 940 interfaces to graphics components for providing a visual display to a user of system 900. In one example, the display can include a touchscreen display.

Accelerators 942 can be a fixed function or programmable offload engine that can be accessed or used by a processor 910. For example, an accelerator among accelerators 942 can provide data compression (DC) capability, cryptography services such as public key encryption (PKE), cipher, hash/authentication capabilities, decryption, or other capabilities or services. In some cases, accelerators 942 can be integrated into a CPU socket (e.g., a connector to a motherboard (or circuit board, printed circuit board, mainboard, system board, or logic board) that includes a CPU and provides an electrical interface with the CPU). For example, accelerators 942 can include a single or multi-core processor, graphics processing unit, logical execution unit single or multi-level cache, functional units usable to independently execute programs or threads, application specific integrated circuits (ASICs), neural network processors (NNPs), programmable control logic, and programmable processing elements such as field programmable gate arrays (FPGAs) or programmable logic devices (PLDs). Accelerators 942 can provide multiple neural networks, CPUs, processor cores, general purpose graphics processing units, or graphics processing units can be made available for use by artificial intelligence (AI) or machine learning (ML) models.

Memory subsystem 920 represents the main memory of system 900 and provides storage for code to be executed by processor 910, or data values to be used in executing a routine. Memory subsystem 920 can include one or more memory devices 930 such as read-only memory (ROM), flash memory, one or more varieties of random access memory (RAM) such as static RAM (SRAM), dynamic RAM (DRAM), synchronous DRAM (SDRAM) and/or or other memory devices, or a combination of such devices. Memory 930 stores and hosts, among other things, operating system (OS) 932 that provides a software platform for execution of instructions in system 900, and stores and hosts applications 934 and processes 936. In one example, memory subsystem 920 includes memory controller 922, which is a memory controller to generate and issue commands to memory 930. The memory controller 922 could be a physical part of processor 910 or a physical part of interface 912. For example, memory controller 922 can be an integrated memory controller, integrated onto a circuit within processor 910.

System 900 can also optionally include one or more buses or bus systems between devices, such memory buses, graphics buses, and/or interface buses. Buses or other signal lines can communicatively or electrically couple components together, or both communicatively and electrically couple the components. Buses can include physical communication lines, point-to-point connections, bridges, adapters, controllers, or other circuitry or a combination. Buses can include, for example, one or more of a system bus, a peripheral component interface (PCI) or PCI express (PCIe) bus, a Hyper Transport or industry standard architecture (ISA) bus, a small computer system interface (SCSI) bus, a universal serial bus (USB), or a Firewire bus.

In one example, system 900 includes interface 914, which can be coupled to interface 912. In one example, interface 914 represents an interface circuit, which can include standalone components and integrated circuitry. In one example, user interface components or peripheral components, or both, couple to interface 914. Network interface 950 provides system 900 the ability to communicate with remote devices (e.g., servers or other computing devices) over one or more networks. Network interface 950 can include an Ethernet adapter, wireless interconnection components, cellular network interconnection components, USB, or other wired or wireless standards-based or proprietary interfaces. Network interface 950 can transmit data to a device that is in the same data center or rack or a remote device, which can include sending data stored in memory.

Some examples of network interface 950 are part of an infrastructure processing unit (IPU) or data processing unit (DPU), or used by an IPU or DPU. An xPU can refer at least to an IPU, DPU, GPU, GPGPU (general purpose computing on graphics processing units), or other processing units (e.g., accelerator devices). An IPU or DPU can include a network interface with one or more programmable pipelines or fixed function processors to perform offload of operations that could have been performed by a CPU. The IPU or DPU can include one or more memory devices.

In one example, system 900 includes one or more input/output (I/O) interface(s) 960. I/O interface 960 can include one or more interface components through which a user interacts with system 900 (e.g., audio, alphanumeric, tactile/touch, or other interfacing). Peripheral interface 970 can include additional types of hardware interfaces, such as, for example, interfaces to semiconductor fabrication equipment and/or electrostatic charge management devices.

In one example, system 900 includes storage subsystem 980. Storage subsystem 980 includes storage device(s) 984, which can be or include any conventional medium for storing data in a nonvolatile manner, such as one or more magnetic, solid state, and/or optical based disks. Storage 984 can be generically considered to be a “memory,” although memory 930 is typically the executing or operating memory to provide instructions to processor 910. Whereas storage 984 is nonvolatile, memory 930 can include volatile memory (e.g., the value or state of the data is indeterminate if power is interrupted to system 900). In one example, storage subsystem 980 includes controller 982 to interface with storage 984. In one example controller 982 is a physical part of interface 912 or processor 910 or can include circuits or logic in both processor 910 and interface 914.

A power source (not depicted) provides power to the components of system 900. More specifically, power source typically interfaces to one or multiple power supplies in system 900 to provide power to the components of system 900.

Exemplary systems may be implemented in various types of computing, smart phones, tablets, personal computers, and networking equipment, such as switches, routers, racks, and blade servers such as those employed in a data center and/or server farm environment.

### EXAMPLES

A microelectronic device can comprise: a semiconducting substrate; a plurality of conducting metal traces wherein the conducting metal traces are in a dielectric material, wherein the dielectric material is on the substrate, and wherein the conducting metal traces form microelectronic circuits; one or more test pads wherein a first one of the one or more test pads comprises a first cavity wherein the first cavity has sidewalls, wherein the sidewalls of the first cavity have a layer of metal; and wherein the layer of metal is in electrical contact with the substrate; and a second cavity wherein the second cavity is in region comprise a conducting metal trace. The second cavity can contain implanted ions. The microelectronic device can also comprise a third cavity wherein the third cavity is in a second one of the one or more test pads wherein the third cavity has sidewalls that do not have a metal layer. The third cavity can contain implanted ions. The semiconducting substrate can be a silicon substrate or a silicon-on-insulator substrate. The semiconducting substrate can be comprised of silicon, gallium arsenide, germanium, indium antimonide, lead telluride, indium phosphide, indium antimonide, indium gallium arsenide, or gallium antimonide. The conducting metal traces can be comprised of copper. The dielectric material can be silicon dioxide, silicon nitride, silicon carbide, silicon carbonitride, fluorine-doped silicon dioxide, or carbon-doped silicon dioxide.

A method for imaging microelectronic circuits can comprise: selecting a microelectronic device for analysis wherein the microelectronic device comprises conducting metal traces in a dielectric material; milling a first cavity in a surface of the microelectronic device wherein the first cavity grounds a first portion of the microelectronic device; milling a second cavity in the microelectronic device wherein the second cavity disconnects the first portion of the microelectronic device from other portions of the microelectronic device; and creating a voltage contrast image of the first portion of the microelectronic device. The first cavity can be in a test pad of the microelectronic device. An ion beam can be used to mill the first cavity. The voltage contrast image can be created in a scanning electron microscope or with an ion beam. The microelectronic device can comprise a semiconductor substrate and the first cavity can ground a portion of the microelectronic device to the semiconductor substrate. The method can also include milling the first cavity a second time to unground the first portion of the microelectronic device. The method of claim 9 wherein the microelectronic device is on a semiconductor wafer. The method can also include determining a location of a fault in the microelectronic device.

At least one machine-readable storage medium can comprise non-transitory instructions, that when executed by a processor, cause a device to: select a microelectronic device for analysis; mill a first cavity in a surface of the microelectronic device wherein the first cavity grounds a first portion of the microelectronic device; mill a second cavity in the microelectronic device wherein the second cavity disconnects the first portion of the microelectronic device from other portions of the microelectronic device; and create a voltage contrast image of the first portion of the microelectronic device. A location of the second cavity can be determined through image recognition. An ion beam can be used to mill the first cavity. The voltage contrast image can be created in a scanning electron microscope or with an ion beam.

Besides what is described herein, various modifications can be made to what is disclosed and implementations of the invention without departing from their scope. Therefore, the illustrations and examples herein should be construed in an illustrative, and not a restrictive sense. The scope of the invention should be measured solely by reference to the claims that follow.

What is claimed is:

1. A microelectronic device comprising:
a semiconducting substrate;
a plurality of conducting metal traces wherein the conducting metal traces are in a dielectric material, wherein the dielectric material is on the substrate, and wherein the conducting metal traces form microelectronic circuits;
one or more test pads wherein a first one of the one or more test pads comprises a first cavity wherein the first cavity has sidewalls, wherein the sidewalls of the first cavity have a layer of metal; and wherein the layer of metal is in electrical contact with the substrate; and
a second cavity wherein the second cavity is in region comprising a conducting metal trace.

2. The microelectronic device of claim 1 wherein the second cavity contains implanted ions.

3. The microelectronic device of claim 1 also comprising a third cavity wherein the third cavity is in a second one of the one or more test pads wherein the third cavity has sidewalls that do not have a metal layer.

4. The microelectronic device of claim 3 wherein the third cavity contains implanted ions.

5. The microelectronic device of claim 1 wherein the semiconducting substrate is a silicon substrate or a silicon-on-insulator substrate.

6. The microelectronic device of claim 1 wherein the semiconducting substrate is comprised of silicon, gallium arsenide, germanium, indium antimonide, lead telluride, indium phosphide, indium antimonide, indium gallium arsenide, or gallium antimonide.

7. The microelectronic device of claim 1 wherein the conducting metal traces are comprised of copper.

8. The microelectronic device of claim 1, wherein the dielectric material is silicon dioxide, silicon nitride, silicon carbide, silicon carbonitride, fluorine-doped silicon dioxide, or carbon-doped silicon dioxide.

9. A method for imaging microelectronic circuits comprising:
selecting a microelectronic device for analysis wherein the microelectronic device comprises conducting metal traces in a dielectric material;
milling a first cavity in a surface of the microelectronic device wherein the first cavity grounds a first portion of the microelectronic device;
milling a second cavity in the microelectronic device wherein the second cavity disconnects the first portion of the microelectronic device from other portions of the microelectronic device; and
creating a voltage contrast image of the first portion of the microelectronic device.

10. The method of claim 9 wherein the first cavity is in a test pad of the microelectronic device.

11. The method of claim 9 wherein an ion beam is used to mill the first cavity.

12. The method of claim 9 wherein the voltage contrast image is created in a scanning electron microscope or with an ion beam.

13. The method of claim 9 wherein the microelectronic device comprises a semiconductor substrate and the first cavity grounds a portion of the microelectronic device to the semiconductor substrate.

14. The method of claim 9 also including milling the first cavity a second time to unground the first portion of the microelectronic device.

15. The method of claim 9 wherein the microelectronic device is on a semiconductor wafer.

16. The method of claim 9 also including determining a location of a fault in the microelectronic device.

17. At least one machine-readable storage medium comprising non-transitory instructions, that when executed by a processor, cause a device to:
select a microelectronic device for analysis;
mill a first cavity in a surface of the microelectronic device wherein the first cavity grounds a first portion of the microelectronic device;
mill a second cavity in the microelectronic device wherein the second cavity disconnects the first portion of the microelectronic device from other portions of the microelectronic device; and
create a voltage contrast image of the first portion of the microelectronic device.

18. The least one machine-readable storage medium of claim 17 wherein, a location of the second cavity is determined through image recognition.

19. The least one machine-readable storage medium of claim 17 wherein an ion beam is used to mill the first cavity.

20. The least one machine-readable storage medium of claim 17 wherein the voltage contrast image is created in a scanning electron microscope or with an ion beam.
